(19) United States
(12) Patent Application Publication
(10) Pub. No.: US 2005/0083223 A1
(43) Pub. Date: Apr. 21, 2005

(54) Resolution enhanced folding amplifier

(76) Inventor: Don C. Devendorf, Carlsbad, CA (US)

Correspondence Address: David T. Yang, Esq.;Morrison & Foerster LLP, Suite 3500, 555 West Fifth Street, Los Angeles, CA, 90013-1024, US

(21) Appl. No.: 10/967,963

(22) Filed: Oct. 19, 2004

Related U.S. Application Data
(60) Provisional application No. 60/512,645, filed on Oct. 20, 2003.

(51) Int. Cl. H03M 1/12

(52) U.S. Cl. 341/156

(57) ABSTRACT

A folding amplifier. The novel folding amplifier includes a first circuit for receiving an input signal and a plurality of reference signals and in accordance therewith generating a plurality of differential signals, a second circuit for receiving the differential signals and in accordance therewith generating first and second output signals for each differential signal, and a third circuit for combining selected output signals to generate a folding signal. The first circuit is implemented using a plurality of differential gain stages that drive the second circuit, comprised of a plurality of folding stages. The gain of the differential gain stages and the separation between reference signals is chosen such that adjacent folding stages do not conduct simultaneously.

### CROSS-REFERENCE TO RELATED APPLICATIONS

This application claims the benefit of U.S. Provisional Application No. 60/512,645, filed Oct. 20, 2003, the disclosure of which is hereby incorporated by reference.

### BACKGROUND OF THE INVENTION

1. Field of the Invention

The present invention relates to electronics. More specifically, the present invention relates to folding amplifiers and analog to digital converters.

2. Description of the Related Art

Analog to digital converters are widely used for converting analog signals to corresponding digital signals for many electronic circuits. For example, a large dynamic range, high-speed analog to digital converter (ADC) may find application in communications, radar, electronic warfare, and medical electronics applications. In the field of analog to digital conversion, there continue to be many driving goals, such as speed, increased number of bits (relating to dynamic range and spur-free operation), power consumption, and size. Two of the most critical specifications remain speed and dynamic range.

Numerous methods exist for performing analog to digital conversion. The fastest ADC architecture is called “flash” conversion. A flash ADC produces an X-bit digital output in one step using a comparator bank comprised of 2^{X}−1 parallel comparators. Flash ADCs, however, need a large number of comparators that typically require large areas and have high power consumption. In practice, this architecture is limited in dynamic range to about 8 bits, since the number of comparators grows rapidly as the number of bits X becomes larger.

Folding analog to digital converters provide for an integrated circuit approach to a high speed, moderate dynamic range encoder. The use of folding amplifiers enables folding ADCs to achieve the speed of flash ADCs while reducing the number of components required with a commensurate reduction in power consumption. Folding ADCs are therefore particularly well suited for low power applications. A folding ADC typically employs a folding amplifier with a number of folding stages to process an analog input signal by generating a transfer function that divides the input signal range into a number of linear segments. A folding ADC processes “fine bits” and “coarse bits” in parallel. The folding amplifier takes the input signal, divides the input range into 2^{N} segments (where N is the number of coarse bits), and maps all 2^{N} ranges onto a single range. All coarse information is thus lost at this point. The resulting signal is then processed to find the fine bit information. This is typically accomplished using a flash converter with 2^{M}−1 parallel comparators (where M is the number of fine bits, and X=M+N is the total number of bits for the analog to digital conversion). Thus, by using a folding amplifier, only 2^{M}−1 comparators are needed instead of 2^{M+N}−1. The coarse bit information is derived in parallel, by determining which of the 2^{N} segments contains the input. The coarse and fine bits are then combined to form the final digital output word.

A folding amplifier is typically implemented with a plurality of cross-coupled differential pairs, each differential pair having one transistor coupled to the input signal and the other transistor coupled to a reference voltage, each differential pair coupled to a different reference voltage such that the voltage levels are equally spaced. With folding ADCs, it is desirable to generate as many bits of the final output word as possible in the folding stages. There is, however, a limit on the number of bits that can be implemented in the folding stages because significant errors are generated when the separation between reference voltages is reduced from the optimum separation. This folding stage limit in turn limits the overall dynamic range of the ADC if the total errors including harmonic distortion (THD) levels are to be consistent with the dynamic range.

Hence, there is a need in the art for an improved folding ADC having a larger dynamic range than prior art systems.

### SUMMARY OF THE INVENTION

The need in the art is addressed by the resolution enhanced folding amplifier of the present invention. The novel folding amplifier includes a first circuit for receiving an input signal and a plurality of reference signals and in accordance therewith generating a plurality of differential signals, a second circuit for receiving the differential signals and in accordance therewith generating first and second output signals for each differential signal, and a third circuit for combining selected output signals to generate a folding signal. The first circuit is implemented using a plurality of differential gain stages that drive the second circuit, comprised of a plurality of folding stages. The gain of the differential gain stages and the separation between reference signals is chosen such that adjacent folding stages do not conduct simultaneously.

### BRIEF DESCRIPTION OF THE DRAWINGS

FIG. 1 is a simplified block diagram of an illustrative embodiment of a folding ADC designed in accordance with the teachings of the present invention.

FIG. 2 is a graph of folding amplifier output Vₒᵤₜ vs. input voltage Vᵢₙ for an example folding ADC, illustrating the folding concept.

FIG. 3 is a simplified schematic diagram of a conventional folding amplifier.

FIG. 4 is a graph of the transfer function of one folding stage, showing the output current I_{C} at the collector of one of the transistors of the differential pair vs. the input voltage Vᵢₙ.

FIG. 5 is a graph of Vₒᵤₜ vs. Vᵢₙ for an example folding amplifier.

FIG. 6 is a graph of the transfer function of a conventional folding amplifier, illustrating the clipping effect that occurs if the reference voltage separation ΔV_{REF} is decreased from the optimal separation.

FIG. 7 is a simplified schematic diagram of an illustrative embodiment of a folding amplifier designed in accordance with the teachings of the present invention.

### DESCRIPTION OF THE INVENTION

Illustrative embodiments and exemplary applications will now be described with reference to the accompanying drawings to disclose the advantageous teachings of the present invention.

While the present invention is described herein with reference to illustrative embodiments for particular applications, it should be understood that the invention is not limited thereto. Those having ordinary skill in the art and access to the teachings provided herein will recognize additional modifications, applications, and embodiments within the scope thereof and additional fields in which the present invention would be of significant utility.

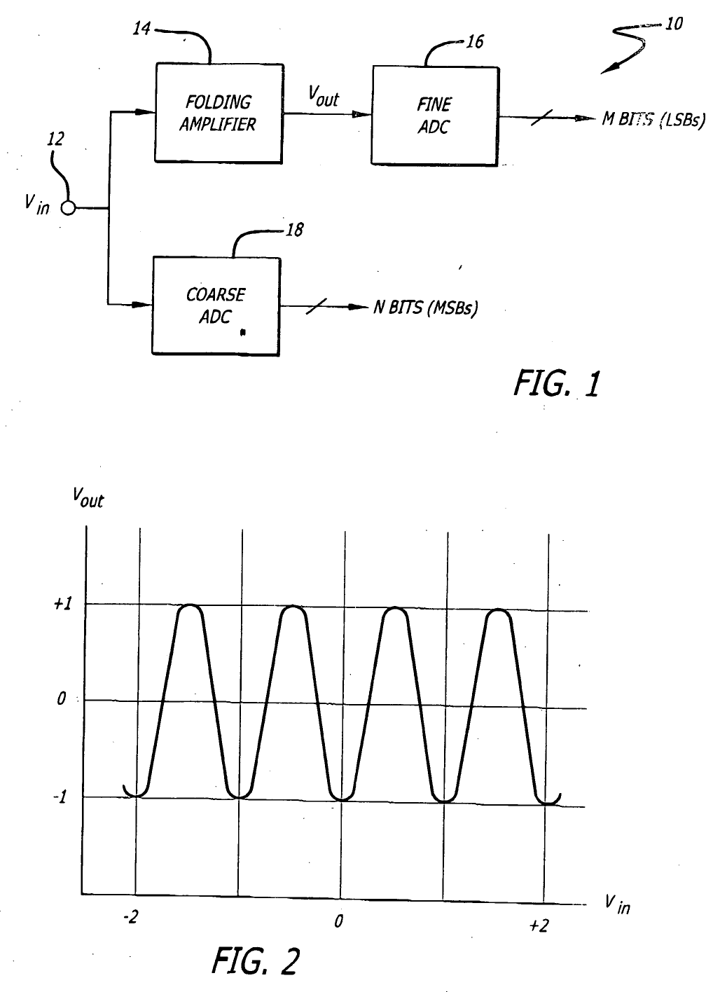

FIG. 1 is a simplified block diagram of an illustrative embodiment of a folding analog to digital converter (ADC) 10 designed in accordance with the teachings of the present invention. The folding ADC 10 includes an input terminal 12 for receiving an analog input signal Vᵢₙ, which is input to a folding amplifier 14. The folding amplifier 14 is also adapted to receive a plurality of reference voltages, which are not shown in FIG. 1 for simplicity. The folding amplifier takes the input voltage, Vᵢₙ, and “folds” it into 2^{N} segments, where N is the number of coarse bits or most significant bits (MSBs), mapping all 2^{N} input ranges onto a single output range. This relationship is shown in FIG. 2.

FIG. 2 is a graph of folding amplifier output Vₒᵤₜ vs. input voltage Vᵢₙ for an example folding ADC, illustrating the folding concept. In the example shown, the input signal Vᵢₙ ranges from −2 V to +2 V, and the folding ADC is adapted to generate N=3 coarse bits. The folding amplifier 14 divides the input range into 2^{N}=8 segments (from −2 V to −1.5 V, −1.5 V to −1 V, −1 V to −0.5 V, −0.5 V to 0 V, 0 V to 0.5 V, 0.5 V to 1 V, 1 V to 1.5 V, and 1.5 V to 2 V). All of the 8 segments are mapped onto a single output range, from −1 V to +1 V in the example of FIG. 2. The transfer function of the folding amplifier 14 therefore resembles a sawtooth function.

Returning to FIG. 1, the output Vₒᵤₜ of the folding amplifier 14 is input to a fine ADC 16 for converting the output signal Vₒᵤₜ to an M-bit digital word. These M bits will comprise the least significant bits (LSBs) of the final output. The fine ADC 16 can be implemented using a flash converter comprised of 2^{M}−1 comparators. The folding ADC 10 also includes a circuit, such as a coarse ADC 18, for determining which of the 2^{N} segments from the folding amplifier 14 contains the input. Each segment can be decoded uniquely resulting in an N-bit word. These N bits will be the MSBs of the final output word. The coarse ADC 18 can be implemented using a second flash converter. The final output of the folding ADC 10 is an X-bit digital word representing the input signal Vᵢₙ, where X=N+M.

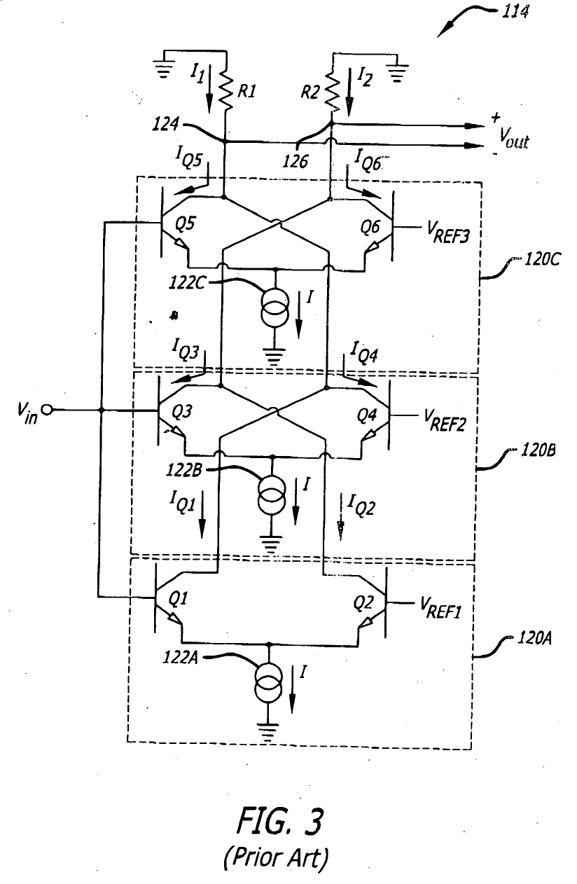

FIG. 3 is a simplified schematic diagram of a conventional folding amplifier 114. The folding amplifier 114 includes a plurality of folding stages 120, typically 2^{N}−1. In the example of FIG. 3, only three folding stages 120A, 120B, and 120C are shown for simplicity. The folding amplifier 114 can have several more folding stages. It is desirable, in fact, to implement as many folding stages as possible without increasing distortion or decreasing accuracy of the following flash converter.

Each folding stage 120 includes a differential pair of transistors: Q1 and Q2 in the first stage 120A, Q3 and Q4 in the second stage 120B, and Q5 and Q6 in the third stage 120C. The base of the first transistor (Q1, Q3, and Q5), hereinafter called the input transistor, of each differential pair is coupled to the input signal Vᵢₙ. The base of the second transistor (Q2, Q4, and Q6), hereinafter called the reference transistor, of each differential pair is coupled to a reference voltage source (V_{REF1}, V_{REF2}, and V_{REF3}, respectively). Each differential pair is supplied with a different reference voltage such that the voltage levels are equally spaced by a voltage corresponding to the value of one LSB apart. The emitters of the two transistors in each differential pair are coupled together and connected to a current source (labeled 122A in the first folding stage 120A, 122B in the second stage 120B, and 122C in the third stage 120C) of value I.

The collectors of one of the transistors (Q1, Q4, and Q5) of the differential pairs are all coupled to a first summing node 124, while the collectors of the other transistors (Q2, Q3, and Q6) of the differential pairs are all coupled to a second summing node 126. The connections of consecutive folding stages are alternated such that, if in one folding stage the reference transistor has its collector coupled to the first summing node 124, in the adjacent folding stage, the reference transistor has its collector coupled to the second summing node 126. Thus, the folding stages form a ladder of cross-coupled differential pairs.

The first summing node 124 is connected to ground through a resistor R1, and the second summing node 126 is connected to ground through a resistor R2. The output Vₒᵤₜ of the folding amplifier 114 is taken from the voltage difference between the first and second summing nodes 124 and 126.

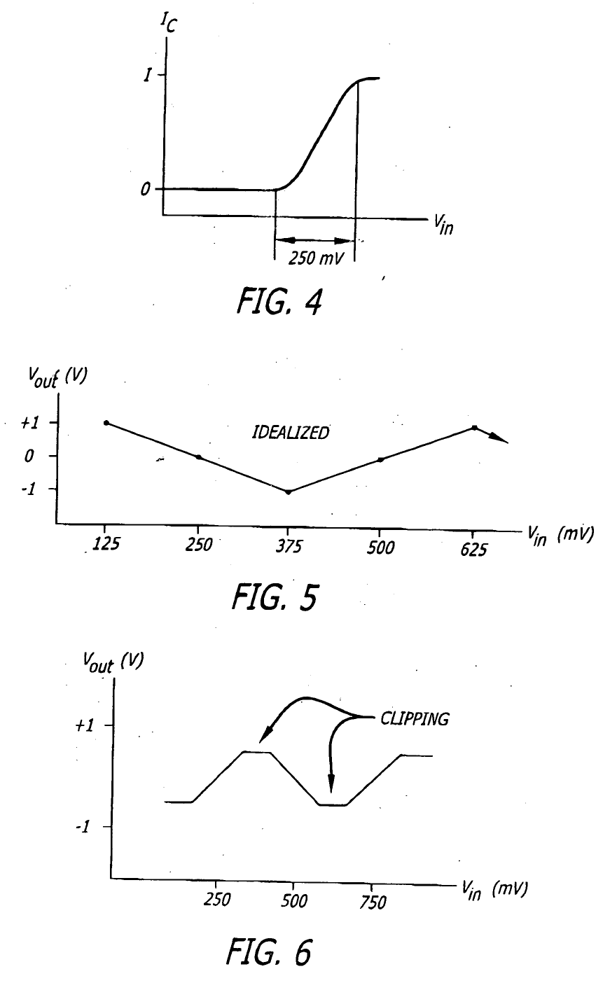

FIG. 4 is a graph of the transfer function of one folding stage, showing the output current I_{C} at the collector of one of the transistors of a differential pair vs. the input voltage Vᵢₙ. As shown, the transistor switches from off (I_{C}=0) to on (I_{c}=I) with a differential transition of 250 mV (this value varies depending on the process technology, 250 mV is typical for common technologies). This is the optimum voltage separation between the reference voltage levels.

A numerical example will now be given to illustrate the operation of the folding amplifier 114. For the purposes of this discussion, the range of Vᵢₙ is set between −2 V to +2 V (this is reasonable for high speed applications). Let V_{REF1}=250 mV, V_{REF2}=500 mV, and V_{REF3}=750 mV. Therefore, for an LSB of the folding stage equal to 0.25 V and an input range of +/− 2 V or 4 V total, there are 4 divided by 0.25 or 16 levels, which is consistent with a 4-bit word (remember that only three folding stages are shown in FIG. 3 for simplicity; a 4-bit folding amplifier would actually have 2⁴−1=15 folding stages).

FIG. 5 is a graph of Vₒᵤₜ vs. Vᵢₙ for an example folding amplifier. For very low input voltages Vᵢₙ, the input transistors are all off and the reference transistors are on. As Vᵢₙ increases, after reaching a first threshold voltage (125 mV in the example of FIG. 5), the input transistor Q1 of the first folding stage begins conducting until, after a specific input voltage range (250 mV for this example), the differential pair has switched with the input transistor Q1 fully on and the reference transistor Q2 off. As Vᵢₙ continues to increase, after a second threshold voltage (375 mV in this example), the differential pair of the next folding stage switches in a similar manner, followed by the following folding stage after a third threshold voltage (625 mV in this example).

Let the input voltage Vᵢₙ=125 mV. The voltages at the base of Q1, Q3, and Q5 are equal to Vᵢₙ=125 mV, the voltage at the base of Q2 is equal to V_{REF1}=250 mV, the voltage at the base of Q4 is equal to V_{REF2}=500 mV, and the voltage at the base of Q6 is equal to V_{REF3}=750 mV. Therefore, Q1 is off (having a collector current I_{Q1}=0), Q2 is on (having a collector current I_{Q2}=I), Q3 is off (having a collector current I_{Q3}=0), Q4 is on (having a collector current I_{Q4}=I), Q5 is off (having a collector current I_{Q5}=0), and Q6 is on (having a collector current I_{Q6}=I).

The current I₁ through the resistor R1 is equal to the sum of the collector currents of the transistors coupled to the first summing node 124. Thus, I=I_{Q1}+I_{Q4}+I_{Q5}=0+I+0=I. The current 12 through the resistor R₂ is equal to the sum of the collector currents of the transistors coupled to the second summing node 126. Thus, I₂=I_{Q2}+I_{Q3}+I_{Q6}=I+0+I=2I.

Let Vᵢₙ=187.5 mV. Now Q1 is ¼ on, Q2 is ¾ on, Q3 is off, Q4 is on, Q5 is off, and Q6 is on. Therefore, I₁=¼ I+I+0=1¼ I and I₂=¾ I+0+I=1¾ I.

Now let Vᵢₙ=250 mV. Since the base voltages on Q1 and Q2 are equal, each transistor is on and conducting an equal current of I/2. So, Q1 is ½ on, Q2 is ½ on, Q3 is off, Q4 is on, Q5 is off, and Q6 is on. Therefore, I₁=½I+I+0=1½ I and I₂=½I+0+I=1½ I.

Let Vᵢₙ=312.5 mV. Now Q1 is ¾ on, Q2 is ¼ on, Q3 is off, Q4 is on, Q5 is off and Q6 is on. Therefore, I₁=¾ I+I+0=1¾ I and I₂=¼ I+0+I=1¼ I.

Let Vᵢₙ=375 mV. Now Q1 is on, Q2 is off, Q3 is off, Q4 is on, Q5 is off, and Q6 is on. Therefore, I₁=I+I+0=2 I and I₂=0+0+I=I.

Let Vᵢₙ=437.5 mV. Now Q1 is on, Q2 is off, Q3 is ¼ on, Q4 is ¾ on, Q5 is off, and Q6 is on. Therefore, I₁=I+¾ I+0=1¾ I and I₂=0+¼ I+I=1¼ I.

Let Vᵢₙ=500 mV. Q1 is on, Q2 is off, Q3 is ½ on, Q4 is ½ on, Q5 is off, and Q6 is on. Therefore I₁=I+½ I+0=1½ I and I₂=0+½I+I=1½ I.

Let Vᵢₙ=562.5 mV. Now Q1 is on, Q2 is off, Q3 is ¾ on, Q4 is ¼ on, Q5 is off, and Q6 is on. Therefore, I₁=I+¼ I+0=1¼ I and I₂=0+¾I+I=1¾ I.

Lastly, let Vᵢₙ=625 mV. Now Q1 is on, Q2 is off, Q3 is on, Q4 is off, Q5 is off and Q6 is on. Therefore, I₁=I+0+0=I and I₂=0+I+I=2I.

The output voltage Vₒᵤₜ is given by Vₒᵤₜ=I₂R2−I₁R1. Letting R1=R2=R, Vₒᵤₜ=R(I₂−I₁). R and I are selected to provide optimum speed, distortion, accuracy and voltage gain. For this example, Vₒᵤₜ is scaled to be +/− 1 V. Table 1 gives sample values for I₁, I₂, and Vₒᵤₜ for various values of Vᵢₙ. The values from Table 1 are used in the graph of Vₒᵤₜ vs. Vᵢₙ of FIG. 5.

TABLE 1

| Vᵢₙ (mV) | I₁ | | I₂ | | Vₒᵤₜ = R(I₂ − I₁) | |
|---|---|---|---|---|---|---|
| 125 | | I | 2 | I | +1 | V |
| 187.5 | 1¼ | I | 1¾ | I | +0.5 | V |
| 250 | 1½ | I | 1½ | I | +0 | V |
| 312.5 | 1¾ | I | 1¼ | I | −0.5 | V |
| 375 | 2 | I | | I | −1 | V |
| 437.5 | 1¾ | I | 1¼ | I | −0.5 | V |
| 500 | 1½ | I | 1½ | I | +0 | V |
| 562.5 | 1¼ | I | 1¾ | I | +0.5 | V |
| 625 | | I | 2 | I | +1 | V |
| 687 | 1¼ | I | 1¾ | I | +0.5 | V |
| 750 | 1½ | I | 1½ | I | +0 | V |

A folding ADC using the conventional folding amplifier implementation of FIG. 3 when targeted at high speed, low distortion, low power applications has certain circuit limitations that limit the word length or the dynamic range of the device. For speed, distortion, IC technology, power and noise constraints, the input voltage, Vᵢₙ, will be limited. (A typical range for Vᵢₙ for high speed applications is from +/−2 V, as used in the example above.) In addition, the optimum reference voltage spacing for the folding stages is dependent on the transfer function of the technology selected (see FIG. 4). The. limit on the input voltage Vᵢₙ, coupled with the need to optimize the reference voltages, limits the number of bits N that the folding amplifier can generate. A second limitation is the number of bits that the flash converter following the folding amplifier can encode. Since it is a parallel configuration, the converter requires 2^{M}−1 comparators. In practice, this type of folding ADC when used in high-speed, low distortion, and low power applications has a limit of 8 bits (N=4 and M=4).

For the previous example, the reference voltages were set with an optimal separation of ΔV_{REF}=250 mV, which provides the optimum output voltage swing. As designed, the gain of the folding amplifier is G=Vₒᵤₜ/ΔV_{REF}=2 V/ 0.25=8, and the input voltage Vᵢₙ is constrained to be +/−2 V.

In order to add more folding stages to increase the dynamic range of the ADC, the reference voltage separation ΔV_{REF} must be decreased. Decreasing ΔV_{REF}, however, has a detrimental effect on the transfer characteristic of the folding amplifier. This occurs because adjacent folding stages begin to conduct at the same time (i.e., a differential pair begins to switch before the subsequent pair completely switched). This, in turn, causes I₁ and I₂ to be limited in their swing, which reduces the output voltage swing, Vₒᵤₜ. In effect, the gain of the folding stage is reduced. In fact, if ΔV_{REF} is reduced from 250 mV to 125 mV, the output Vₒᵤₜ goes to 0 V and the folding amplifier becomes a perfect attenuator.

Since the output errors V_{ERROR} can be reflected to the input Vᵢₙ by the equation Vᵢₙ=V_{ERROR}/G, as the gain G drops the equivalent errors are increased. Not only has the gain G of the folding stage decreased with a reduction of ΔV_{REF} but also there is a clipping of the waveform that occurs because the adjacent folding stages are conducting as is shown in FIG. 6. FIG. 6 is a graph of the transfer function of a conventional folding amplifier, illustrating the clipping effect that occurs if the reference voltage separation ΔV_{REF} is decreased from the optimal separation. This distortion of the output waveform adds considerable errors to the converter. Both of these errors, clipping and gain reduction, will contribute to distortion products that limit and degrade the performance of the original device. Thus, if additional folding stages are added to the conventional folding ADC in an attempt to increase its dynamic range, the attendant decreased reference voltage separation will generate distortion products that are greater than the original eight-bit converter, limiting the usefulness of the added stages. The prior art is therefore limited to a folding amplifier that contributes only four bits to the ADC's final eight-bit output word.

The present invention includes a novel folding amplifier that allows for the addition of more folding stages while simultaneously keeping the adjacent folding stages from conducting. This is necessary for optimal performance. The key to this invention is the addition of non-saturating differential output matched gain stages preceding each folding stage. These matched gain stages allow a significant increase to the dynamic range of the ADC while also maintaining the required accuracy and keeping the THD levels appropriate for the extended dynamic range.

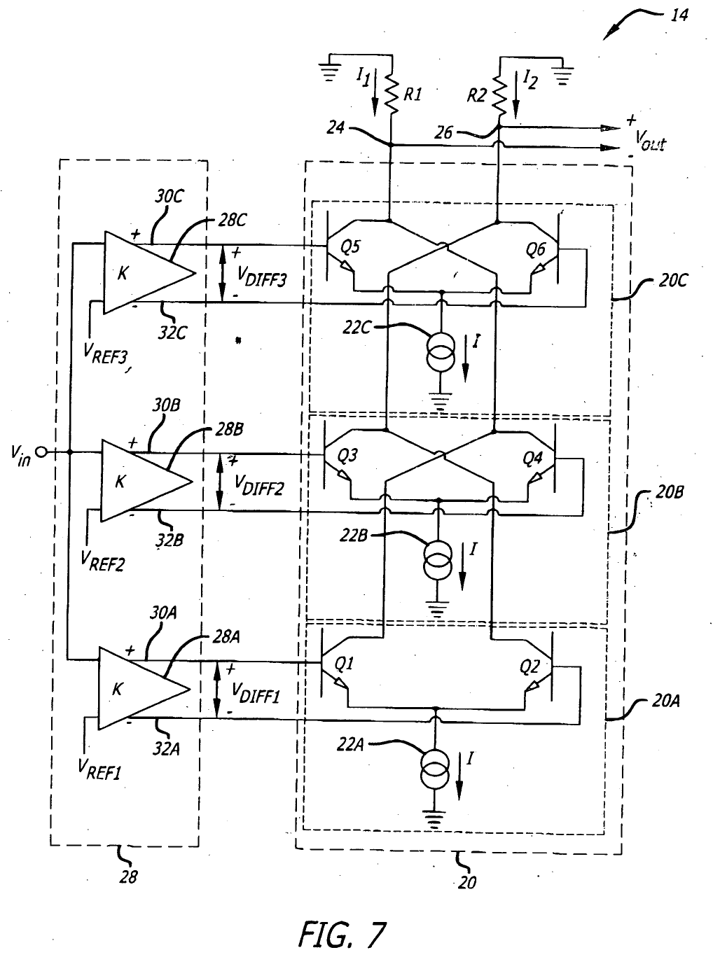

FIG. 7 is a simplified schematic diagram of an illustrative embodiment of a folding amplifier 14 designed in accordance with the teachings of the present invention. The folding amplifier 14 includes a plurality of folding stages 20. In the example of FIG. 7, only three folding stages 20A, 20B, and 20C are shown for simplicity. The folding amplifier 14, however, can have several more folding stages without departing from the scope of the present invention. The number of folding stages is equal to 2^{N}−1, where N is the number of bits generated in the folding amplifier 14 (the MSBs). For a folding ADC application, it is desirable to generate as many bits of the final output word as possible in the folding amplifier 14.

Each folding stage includes a differential pair of transistors: Q1 and Q2 in the first stage 20A, Q3 and Q4 in the second stage 20B, and Q5 and Q6 in the third stage 20C. The emitters of the two transistors in each differential pair are coupled together and connected to a current source (labeled 22A in the first folding stage 20A, 22B in the second stage 20B, and 22C in the third stage 20C) of value I.

In accordance with the teachings of the present invention, the folding amplifier 14 further includes a plurality of differential amplifiers 28, a differential amplifier of gain K preceding each folding stage (in the example of FIG. 7, differential amplifier 28A is coupled to the first folding stage 20A, differential amplifier 28B to the second stage 20B, and differential amplifier 28C to the third stage 20C). Each differential amplifier (28A, 28B, and 28C) is adapted to receive an input signal Vᵢₙ and a reference voltage. Each differential amplifier (28A, 28B, and 28C) is supplied with a different reference voltage (V_{REF1}, V_{REF2}, and V_{REF3}, respectively) such that the voltage levels are equally spaced by a voltage separation ΔV_{REF} corresponding to the value of one LSB apart. The differential amplifiers (28A, 28B, and 28C) each output a differential voltage (V_{DIFF1}, V_{DIFF2}, and V_{DIFF3}, respectively) corresponding to an amplified version of the difference between the input signal Vᵢₙ and the reference voltage (V_{REF1}, V_{REF2}, and V_{REF3}, respectively).

The folding stages 20 are identical to the folding stages 120 of the prior art folding amplifier 114, except the inputs to the folding stages 20 are now the differential outputs from the differential amplifiers 28, instead of the input signal Vᵢₙ and reference voltages as with the prior art. The positive output terminal of the differential amplifier (labeled 30A in the first differential amplifier 28A, 30B in the second differential amplifier 28B, and 30C in the third differential amplifier 28C) is coupled to the base of the first transistor (Q1, Q3, and Q5, respectively), hereinafter called the positive transistor, of the differential pair of each folding stage (20A, 20B, and 20C, respectively). The negative output terminal of the differential amplifier (labeled 32A in the first differential amplifier 28A, 32B in the second differential amplifier 28B, and 32C in the third differential amplifier 28C) is coupled to the base of the second transistor (Q2, Q4, and Q6, respectively), hereinafter called the negative transistor, of the differential pair of each folding stage (20A, 20B, and 20C, respectively).

The collectors of one of the transistors (Q1, Q4, and Q5) of the differential pairs are all coupled to a first summing node 24, while the collectors of the other transistors (Q2, Q3, and Q6) of the differential pairs are all coupled to a second summing node 26. The connections of consecutive folding stages are alternated such that, if in one folding stage the positive transistor has its collector coupled to the first summing node 24, in the adjacent folding stage, the positive transistor has its collector coupled to the second summing node 26. The first summing node 24 is connected to ground through a resistor R1, and the second summing node 26 is connected to ground through a resistor R2. The output Vₒᵤₜ of the folding amplifier 14 is taken from the voltage difference between the first and second summing nodes 24 and 26.

Each folding stage 20 is adapted to receive the differential output of the preceding differential amplifier 28 and in accordance therewith, output first and second output signals at the collectors of the positive and negative transistors, respectively, such that the first output signal gradually transitions from a first level to a second level over a specific voltage range of the input signal Vᵢₙ, and the second output signal transitions from the second level to the first level inversely to the first output signal. Each folding stage 20 is adapted to respond to a different input voltage range (as determined by the reference voltage levels input to the differential amplifiers 28). As discussed below, the novel folding amplifier 14 of the present invention exhibits the same performance as the prior art folding amplifier 114, but allows for the addition of more folding stages without adding distortion.

First, let the gain K of the differential amplifiers 28 be equal to ½. Since the output of the differential amplifier 28 is differential, setting K=½ is equivalent to a stage gain of unity. The differential voltage V_{DIFF1} output from the differential amplifier 28 is given by V_{DIFF1}=2K(Vᵢₙ−V_{REF1}). For K=½, V_{DIFF1} is therefore equal to the difference between the input voltage Vᵢₙ and the reference voltage V_{REF1}. The differential voltages V_{DIFF1} are input to the differential pairs of the folding stages 20. In the prior art folding amplifier 114, as shown in FIG. 3, the folding stages 120 also respond to the difference between the input voltage Vᵢₙ (which is directly input to the input transistor in the prior art) and the reference voltage V_{REF1} (which is directly input to the reference transistor in the prior art). The folding stages 20 of the present invention with K set to ½ therefore perform exactly as in the prior art.

Table 2 shows the differential voltages (the differences between the base voltages V_{B}) across the transistors Q1 and Q2, Q3 and Q4, and Q5 and Q6 in the prior art folding amplifier 114, and compares them to the differential voltages V_{DIFF1}, V_{DIFF2} and V_{DIFF3} output from the differential amplifiers 28 (which is subsequently input to the folding stages 20) in the folding amplifier 14 of the present invention, with the gain K set to ½, V_{REF1}=250 mV, V_{REF2}=500 mV, and V_{REF3}=750 mV. (In the illustrative example, once the differential voltage input to a folding stage is greater than 125 mV or lower than −125 mV, it ceases to impact the output, as noted by an asterisk (*) in Table 2.) The differential voltages seen at the input of the folding stages are identical for both cases.

TABLE 2

| | | Prior Art (mV) | | | | | |
|---|---|---|---|---|---|---|---|
| | | V_{BQ1}- | V_{BQ3}- | V_{BQ5}- | Present Invention (mV) | | |
| | Vᵢₙ | V_{BQ2} | V_{BQ4} | V_{BQ6} | V_{DIFF1} | V_{DIFF2} | V_{DIFF3} |
| | 125 | −125 | * | * | −125 | * | * |
| | 187.5 | −62.5 | * | * | −62.5 | * | * |
| V_{REF1} | 250 | 0 | * | * | 0 | * | * |
| | 312.5 | 62.5 | * | * | 62.5 | * | * |
| | 375 | 125 | −125 | * | 125 | −125 | * |
| | 437.5 | * | −62.5 | * | * | −62.5 | * |
| V_{REF2} | 500 | * | 0 | * | * | 0 | * |
| | 562.5 | * | 62.5 | * | * | 62.5 | * |
| | 625 | * | 125 | −125 | * | 125 | −125 |
| | 682.5 | * | * | −62.5 | * | * | −62.5 |
| V_{REF3} | 750 | * | * | 0 | * | * | 0 |

Now, set the gain K to 1, and decrease the reference voltage separation ΔV_{REF} between V_{REFi} and V_{REFi+1} from 250 mV to 125 mV (which could not be done with the prior art implementation without adding distortion to the system output). Table 3 shows the resulting differential voltages V_{DIFFi} for various inputs Vᵢₙ. The differential voltages V_{DIFFi} seen at the inputs to the folding stages 20 are the same as in the prior example. Adjacent folding stages 20 therefore do not conduct at the same time, and the gain reduction and clipping problems of the prior art implementation are eliminated.

TABLE 3

| | Vᵢₙ (mV) | V_{DIFF1} (mV) | V_{DIFF2} (mV) | V_{DIFF3} (mV) |
|---|---|---|---|---|
| V_{REF1} | 125 | 0 | * | * |
| | 156.25 | 62.5 | * | * |
| | 187.5 | 125 | −125 | * |
| | 218.75 | * | −62.5 | * |
| V_{REF2} | 250 | * | 0 | * |
| | 281.25 | * | −62.5 | * |
| | 312.5 | * | 125 | −125 |
| | 343.75 | * | * | −62.5 |
| V_{REF3} | 375 | * | * | 0 |
| | 406.25 | * | * | 62.5 |
| | 437.5 | * | * | 125 |
| | 468.75 | * | * | * |

By decreasing the reference voltage separation ΔV_{REF} and maintaining the same V_{DIFFi}, the folding amplifier 14 of the present invention can have double (or quadruple or more) the number of folding stages while maintaining the same ideal transfer function of the folding stages. This allows the folding stages 20 to provide more bits to the total conversion process without increasing the distortion products, thereby increasing the useful dynamic range of the ADC.

It is easy to see that the number of folding stages 20 could be doubled again by simply increasing the gain stage to K=2. By doing this, the dynamic range of the ADC would increase by 2 bits in comparison with the conventional folding ADC. In the prior configuration the ADC was limited to N=4 and M=4 (a total of 8 bits). Utilizing the configuration of the present invention with N=6 and M=4 results in an ADC with a dynamic range extended to ten-bit performance. This is done with virtually no reduction in performance.

The differential gain stages 28 must be designed to be non-saturating and limiting so that they introduce no distortion products themselves. This, however, is not difficult with the modest gains required.

Thus, the folding amplifier 14 of the present invention utilizes a differential output gain stage (28A, 28B, and 28C) prior to each folding stage (20A, 20B, and 20C, respectively). This permits the reference voltages to be reduced without increasing non-linearities and subsequent distortion products. By reducing the reference voltage levels, more folding stages may be added which will extend the dynamic range of the ADC. The reference voltages, which were previously inputs to each differential pair, have been moved forward to be an input to each of the differential gain stages. The differential outputs of the gain stages now drive the differential pairs in this enhanced implementation.

Thus, the present invention has been described herein with reference to a particular embodiment for a particular application. Those having ordinary skill in the art and access to the present teachings will recognize additional modifications, applications and embodiments within the scope thereof. While the invention has been described with reference to an analog to digital conversion application, the invention is not limited thereto. The novel folding amplifier may be used in other applications without departing from the scope of the present teachings.

It is therefore intended by the appended claims to cover any and all such applications, modifications and embodiments within the scope of the present invention.

Accordingly,

1. A folding amplifier comprising:
first means for receiving an input signal and a plurality of reference signals and in accordance therewith generating a plurality of differential signals;
second means for receiving said differential signals and in accordance therewith generating first and second output signals for each differential signal; and
third means for combining selected output signals to generate a folding signal.

2. The invention of claim 1 wherein said first output signal gradually transitions from a first level to a second level over an input range of said input signal, and said second output signal transitions from said second level to said first level inversely to said first output signal.

3. The invention of claim 2 wherein each differential signal is an amplified difference between said input signal and one of said reference signals.

4. The invention of claim 3 wherein said reference signals are equally spaced by a predetermined reference voltage separation.

5. The invention of claim 4 wherein said first means includes a plurality of differential amplifiers of gain K, each adapted to receive said input signal and one of said reference voltages.

6. The invention of claim 5 wherein said gain K and said predetermined reference voltage separation are chosen such that said input ranges do not overlap.

7. The invention of claim 5 wherein said second means includes a plurality of folding stages, each adapted to receive one of said differential signals.

8. The invention of claim 7 wherein each folding stage includes a differential pair of transistors.

9. The invention of claim 8 wherein each differential amplifier includes a positive output terminal and a negative output terminal.

10. The invention of claim 9 wherein an input of a first transistor of said differential pair is coupled to said positive output terminal and an input of a second transistor of said differential pair is coupled to said negative output terminal.

11. The invention of claim 8 wherein said first and second output signals are the currents output from the collectors of the transistors of said differential pair.

12. The invention of claim 8 wherein the emitters of the transistors of each differential pair are connected in common to a current source.

13. The invention of claim 10 wherein said third means includes a first summing node adapted to combine one of said output signals from each folding stage.

14. The invention of claim 13 wherein said third means further includes a second summing node adapted to combine output signals not combined by said first summing node.

15. The invention of claim 14 wherein said folding stages are cross-coupled such that if the first transistor in a folding stage is coupled to said first summing node, then the first transistor of an adjacent folding stage is coupled to said second summing node.

16. The invention of claim 14 wherein said folding signal is generated from the voltage difference between said first and second summing nodes.

17. A folding amplifier comprising:
a plurality of differential gain stages, each adapted to receive an input signal and a reference voltage, and generate a differential signal corresponding to a difference between said input signal and said reference signal, amplified by a gain K;
a plurality of folding stages, each adapted to receive a differential signal from one of said differential gain stages and in accordance therewith generate first and second output signals, wherein said first output signal gradually transitions from a first level to a second level over an input range of said input signal, and said second output signal transitions from said second level to said first level inversely to said first output signal; and
a first summing node for combining selected output signals from said folding stages to generate a folding signal.

18. The invention of claim 16 wherein each gain stage is supplied with a different reference voltage such that said reference voltages are equally spaced by a predetermined reference voltage separation.

19. The invention of claim 18 wherein said gain K and said predetermined reference voltage separation are chosen such that said input ranges do not overlap.

20. The invention of claim 16 wherein each folding stage includes a differential pair of transistors.

21. The invention of claim 20 wherein each differential gain stage includes a positive output terminal and a negative output terminal.

22. The invention of claim 21 wherein an input of a first transistor of said differential pair is coupled to said positive output terminal and an input of a second transistor of said differential pair is coupled to said negative output terminal.

23. The invention of claim 20 wherein said first and second output signals are the currents output from the collectors of the transistors of said differential pair.

24. The invention of claim 20 wherein the emitters of the transistors of each differential pair are connected in common to a current source.

25. The invention of claim 22 wherein said folding amplifier further includes a second summing node adapted to combine output signals not combined by said first summing node.

26. The invention of claim 25 wherein said folding stages are cross-coupled such that if the first transistor in a folding stage is coupled to said first summing nodes then the first transistor of an adjacent folding stage is coupled to said second summing node.

27. The invention of claim 25 wherein said folding signal is generated from the voltage difference between said first and second summing nodes.

28. A folding analog to digital converter (ADC) comprising:
a folding amplifier comprising:
a plurality of differential gain stages, each adapted to receive an input signal and a reference voltage, and generate a differential signal corresponding to a difference between said input signal and said reference signal, amplified by a gain K;
a plurality of folding stages, each adapted to receive a differential signal from one of said differential gain stages and in accordance therewith generate first and second output signals, wherein said first output signal gradually transitions from a first level to a second level over an input range of said input signal, and said second output signal transitions from said second level to said first level inversely to said first output signal; and
a first summing node for combining selected output signals from said folding stages to generate a folding signal;
a circuit for converting said folding signal to an N-bit digital word corresponding to the least significant bits of the ADC output; and
a circuit for converting said input signal to an M-bit digital word corresponding to the most significant bits of the ADC output.

29. A method for folding a signal including the steps of:
receiving an input signal and a plurality of reference signals, wherein said reference voltages are equally spaced by a predetermined reference voltage separation;
generating a plurality of differential signals, each differential signal corresponding to a difference between an input signal and a reference signal, amplified by a gain K;
generating first and second output signals for each differential signal, wherein said first output signal gradually transitions from a first level to a second level over an input range of said input signal, and said second output signal transitions from said second level to said first level inversely to said first output signal; and
combining selected output signals to generate a folding signal.

30. The invention of claim 27 wherein said method further includes selecting said gain K and said predetermined reference voltage separation such that said input ranges do not overlap.
